(19) United States
(12) Patent Application Publication
(10) Pub. No.: US 2016/0254155 A1
(43) Pub. Date: Sep. 1, 2016

(54) METHOD OF MANUFACTURING SEMICONDUCTOR DEVICE

(71) Applicant: FUJITSU SEMICONDUCTOR LIMITED, Yokohama-shi (JP)

(72) Inventors: Taiji Ema, Yokohama (JP); Toshifumi Mori, Yokohama (JP); Toshiki Miyake, Yokohama (JP); Kenichi Okabe, Yokohama (JP)

(21) Appl. No.: 15/154,670

(22) Filed: May 13, 2016

Related U.S. Application Data
(62) Division of application No. 13/172,465, filed on Jun. 29, 2011.

(30) Foreign Application Priority Data
Sep. 30, 2010 (JP) 2010-220776

(51) Int. Cl. H01L 21/265; H01L 21/8238; H01L 21/311; H01L 21/027; H01L 29/66; H01L 21/306

(52) U.S. Cl. CPC H01L 21/2652; H01L 29/66477; H01L 21/30604; H01L 21/31111; H01L 21/0274; H01L 21/823807; H01L 21/823892

(57) ABSTRACT

A protection film is formed on a semiconductor substrate. Impurity ions are implanted into the semiconductor substrate through the protection film. The impurity is activated to form an impurity layer. The protection film is removed after forming the impurity layer. The semiconductor substrate of a surface portion of the impurity layer is removed after removing the protection film. A semiconductor layer is epitaxially grown above the semiconductor substrate after removing the semiconductor substrate of the surface portion of the impurity layer.

### CROSS REFERENCE TO RELATED APPLICATIONS

This application is a Divisional of U.S. application Ser. No. 13/172,465, filed Jun. 29, 2011, which is based upon and claims the benefit of priority of the prior Japanese Patent Application No. 2010-220776, filed on Sep. 30, 2010, the entire contents of which are incorporated herein by reference.

### FIELD

The embodiments discussed herein are related to a method of manufacturing a semiconductor device.

### BACKGROUND

As semiconductor devices are downsized and highly integrated, the fluctuations of the threshold voltages of the transistors due to statistical fluctuations of the channel impurity becomes conspicuous. The threshold voltage is one of important parameters for determining the performance of the transistors, and to manufacture semiconductor device of high performance and high reliability, it is important to decrease the fluctuations of the threshold voltage due to the statistical fluctuations of the impurity.

As one technique of decreasing the fluctuations of the threshold voltage due to the statistical fluctuations is proposed the technique that a non-doped epitaxial silicon layer is formed on a highly doped channel impurity layer having a steep impurity concentration distribution.

The following are examples of related: U.S. Pat. No. 6,426,279; U.S. Pat. No. 6,482,714; U.S. Patent Publication No. 2009/0108350; A. Asenov, “Suppression of Random Dopant-Induced Threshold Voltage Fluctuations in Sub-0.1-μm MOSFET's with Epitaxial and 5-doped Channels”, IEEE Transactions on Electron Devices, vol. 46, No. 8. p. 1718, 1999; Woo-Hyeong Lee, “MOS Device Structure Development for ULSI: Low Power/High Speed Operation”, Microelectron. Reliab., Vol. 37, No. 9, pp. 1309-1314, 1997; A. Hokazono et al., “Steep Channel Profiles in n/pMOS Controlled by Boron-Doped Si:C Layers for Continual Bulk-CMOS Scaling”, IEDM09-673; and L. Shao et al., “Boron diffusion in silicon: the anomalies and control by point defect engineering”, Materials Science and Engineering R 42, pp. 65-114, 2003.

The inventors of the present application examined the proposed semiconductor devices and have found that the epitaxial layer formed on the channel impurity layer has the crystallinity degraded. The crystallinity of the epitaxial layer much influences the transistor characteristics and resultantly the performance and the reliability of the semiconductor device. The crystallinity of the epitaxial layer is desired to be improved.

### SUMMARY

According to one aspect of an embodiment, there is provided a method of manufacturing a semiconductor device including ion implanting an impurity in a semiconductor substrate, activating the impurity to form an impurity layer in the semiconductor substrate, removing the semiconductor substrate of a surface portion of the impurity layer, and epitaxially growing a semiconductor layer above the semiconductor substrate after removing the semiconductor substrate of the surface portion of the impurity layer.

According to another aspect of an embodiment, there is provided a method of manufacturing a semiconductor device including forming a protection film above a semiconductor substrate, ion implanting an impurity in the semiconductor substrate through the protection film, activating the impurity to form an impurity layer in the semiconductor substrate, removing the protection film after forming the impurity layer, removing the semiconductor substrate of the surface portion of the impurity layer after removing the protection film, and epitaxially growing a semiconductor layer above the semiconductor substrate after removing the semiconductor substrate of the surface portion of the impurity layer.

According to further another aspect of an embodiment, there is provided a method of manufacturing a semiconductor device including forming a first protection film above a semiconductor substrate, forming above the first protection film a first mask exposing a first region and covering a second region, removing the first protection film in the first region by using the first mask, ion implanting a first impurity in the semiconductor substrate in the first region by using the first mask after removing the first protection film in the first region, removing the first mask, activating the first impurity to form a first impurity layer in the semiconductor substrate after removing the first mask, removing the remaining first protection film after forming the first impurity layer, and epitaxially growing a semiconductor layer above the semiconductor substrate after removing the remained first protection film.

The object and advantages of the embodiment will be realized and attained by means of the elements and combinations particularly pointed out in the claims.

It is to be understood that both the foregoing general description and the following detailed description are exemplary and explanatory and are not restrictive of the embodiments, as claimed.

### BRIEF DESCRIPTION OF DRAWINGS

FIGS. 1 and 2 are diagrammatic sectional views illustrating a structure of a semiconductor device according to a first embodiment;

FIGS. 3A-3B, 4A-4B, 5A-5B, 6A-6B, 7A-7B, 8A-8B and 9 are sectional views illustrating a method of manufacturing the semiconductor device according to the first embodiment;

FIG. 10 is a graph illustrating a relationship between the surface roughness of the epitaxial layer and the silicon etching amount;

FIGS. 11, 12, 18 and 19 are graphs illustrating the depth distributions of oxygen in the silicon substrate;

FIGS. 13A-13B, 14A-14B and 15 are sectional views illustrating a method of manufacturing the semiconductor device according to the second embodiment; and

FIGS. 16A-16B and 17A-17B are sectional views illustrating a method of manufacturing a semiconductor device according to a reference example.

### DESCRIPTION OF EMBODIMENTS

### A First Embodiment

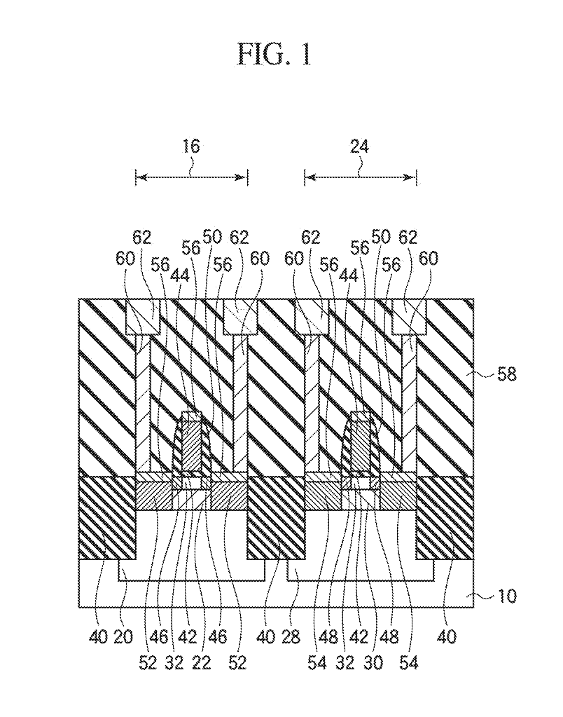

A semiconductor device and a method of manufacturing a semiconductor device according to a first embodiment will be described with reference to FIGS. 1 to 20.

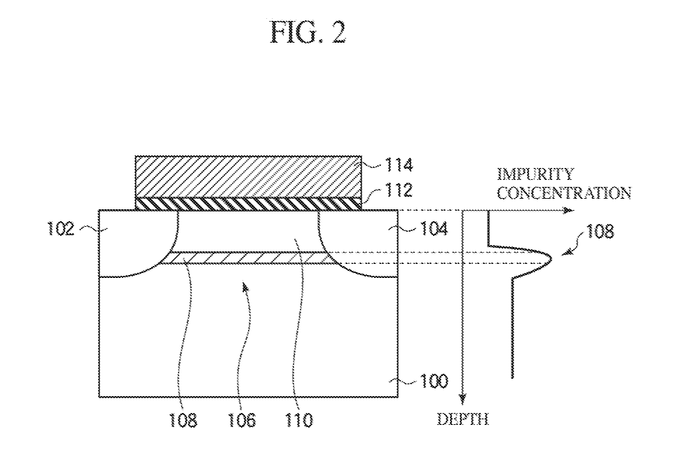

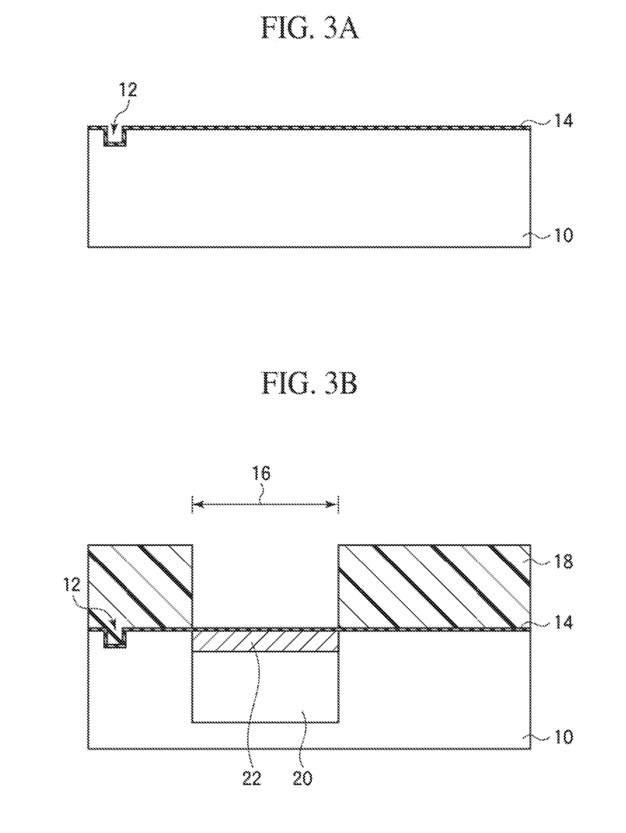

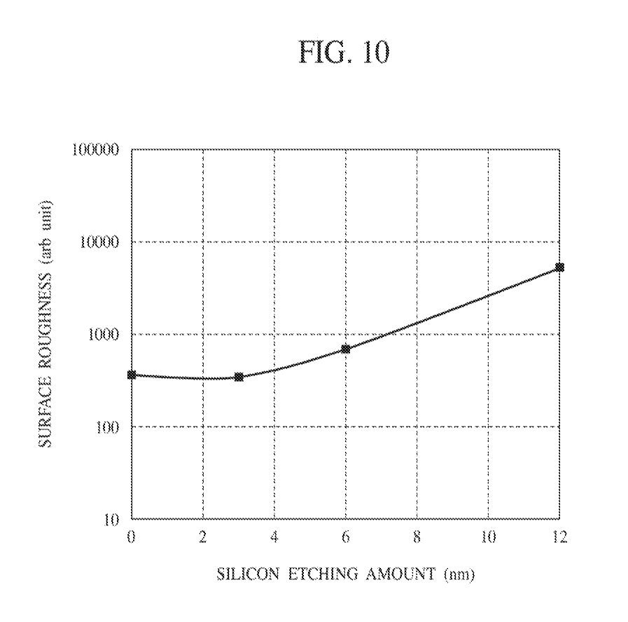

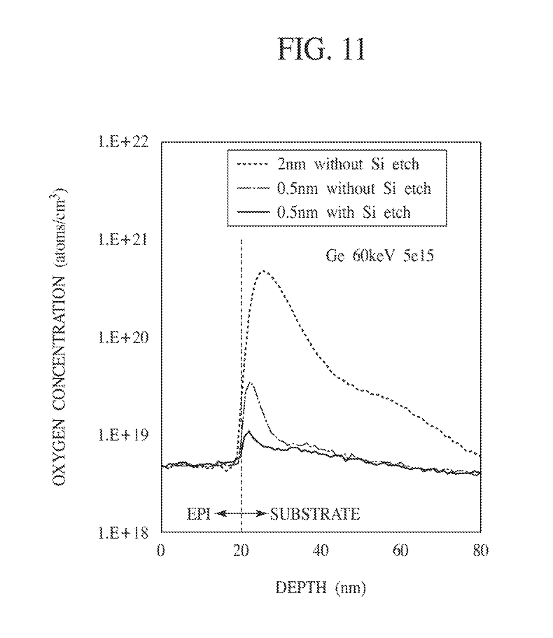

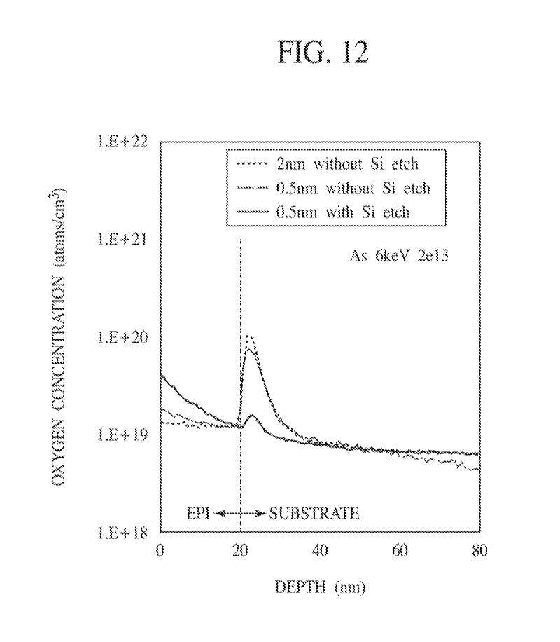

FIGS. 1 and 2 are diagrammatic sectional views illustrating a structure of the semiconductor device according to the present embodiment. FIGS. 3A-9 are sectional views illustrating a method of manufacturing the semiconductor device according to the present embodiment. FIG. 10 is a graph illustrating a relationship between the surface roughness of the epitaxial layer and the silicon etching amount. FIGS. 11 and 12 are graphs illustrating the depth distributions of oxygen in the silicon substrate.

First, the structure of the semiconductor device according to the present embodiment will be described with reference to FIGS. 1 and 2.

An NMOS transistor forming region 16 and a PMOS transistor forming region 24 are provided above a silicon substrate 10.

A p-well 20 and a p-type highly doped impurity layer 22 are formed in the silicon substrate 10 in the NMOS transistor forming region 16. A silicon layer 32 epitaxially grown on the silicon substrate 10 is formed above the p-type highly doped impurity layer 22. A gate insulating film 42 is formed above the silicon layer 32. A gate electrode 44 is formed above the gate insulating film 42. Source/drain regions 52 are formed in the silicon layer 32 and the silicon substrate 10 on both sides of the gate electrode 44. Thus, an NMOS transistor is formed.

An n-well 28 and an n-type highly doped impurity layer 30 are formed in the silicon substrate 10 in the PMOS transistor forming region 24. A silicon layer 32 epitaxially grown on the silicon substrate 10 is formed above the n-type highly doped impurity layer 30. A gate insulating film 42 is formed above the silicon layer 32. a gate electrode 44 is formed above the gate insulating film 42. Source/drain regions 54 are formed in the silicon layer 32 and the silicon substrate 10 on both sides of the gate electrode 44. Thus, a PMOS transistor is formed.

A metal silicide film 56 is formed above the gate electrodes 44 and the source/drain regions 52, 54 of the NMOS transistor and the PMOS transistor.

An inter-layer insulating film 58 is formed above the silicon substrate 10 with the NMOS transistor and the PMOS transistor formed on. Contact plugs 60 connected to the transistors are buried in the inter-layer insulating film 58. Interconnections 62 are connected to the contact plugs 60.

As exemplified in FIG. 2, the NMOS transistor and the PMOS transistor each include in the channel region 106, a highly doped impurity layer 108 having a steep impurity concentration distribution, and a non-doped silicon layer 110 epitaxially grown on the highly doped impurity layer 108. Such transistor structure is effective to suppress the threshold voltage fluctuations of the transistors due to the statistical fluctuations of the impurity.

Next, the method of manufacturing the semiconductor device according to the present embodiment will be described with reference to FIGS. 3A to 9.

First, a trench 12 to be used as the mark for the mask alignment is formed in a region other than the product to be formed region of the silicon substrate 10 (e.g., a scribe region) by photolithography and etching.

In the method of manufacturing the semiconductor device according to the present embodiment, the wells and the channel impurity layers are formed before the device isolation insulating film 40 is formed. The trench 12 is used as the mark for the mask alignment in the lithography process made before the device isolation insulating film 40 is formed (e.g., the lithography process for forming the wells and the channel impurity layers). The wells and the channel impurity layers are formed before the device isolation insulating films 40 are formed so as to suppress the film thickness decrease of the device isolation insulating film 40 in removing the silicon oxide films 14, etc.

Next, a silicon oxide film 14 as the protection film of the surface of the silicon substrate 10 is formed above the entire surface of the silicon substrate 10 by, e.g., thermal oxidation method (FIG. 3A).

Next, a photoresist film 18 exposing the NMOS transistor forming region 16 and covering the rest region is formed by photolithography. The trench 12 is used as the alignment mark for the alignment for the photolithography.

Next, ion implantation is made with the photoresist film 18 as the mask to form a p-well 20 and a p-type highly doped impurity layer 22 in the NMOS transistor forming region 16 (FIG. 3B).

The p-well 20 is formed, e.g., by implanting boron ions (B⁺) respectively in 4 directions tilted to the normal direction of the substrate under the conditions of 150 keV acceleration energy and 7.5×10¹² cm⁻² dose. The p-type highly doped impurity layer 22 is formed, e.g., by respectively implanting germanium ions (Ge⁺) under the conditions of 50 keV acceleration energy and 5×10¹⁴ cm⁻², carbon ions (C⁺) under the conditions of 3 keV acceleration energy and 3×10¹⁴ cm² and boron ions (B⁺) under the conditions of 2 keV acceleration energy and 3×10¹³ cm². Germanium acts to amorphize the silicon substrate 10 to thereby prevent the channeling of the boron ions and amorphize the silicon substrate 10 to increase the probability of positioning the carbon at the lattice points. The carbon positioned at the lattice points acts to suppress the diffusion of boron. In view of this, it is preferable to ion implant germanium before carbon and boron forming the p-type highly doped impurity layer 22, and the p-well 20 is formed before the p-type highly doped impurity layer 22.

Next, the photoresist film 18 is removed by, e.g., asking method.

Then, a photoresist film 26 exposing the PMOS transistor forming region 24 and covering the rest region is formed by photolithography. The trench 12 is used as the alignment mark for the alignment for the photolithography.

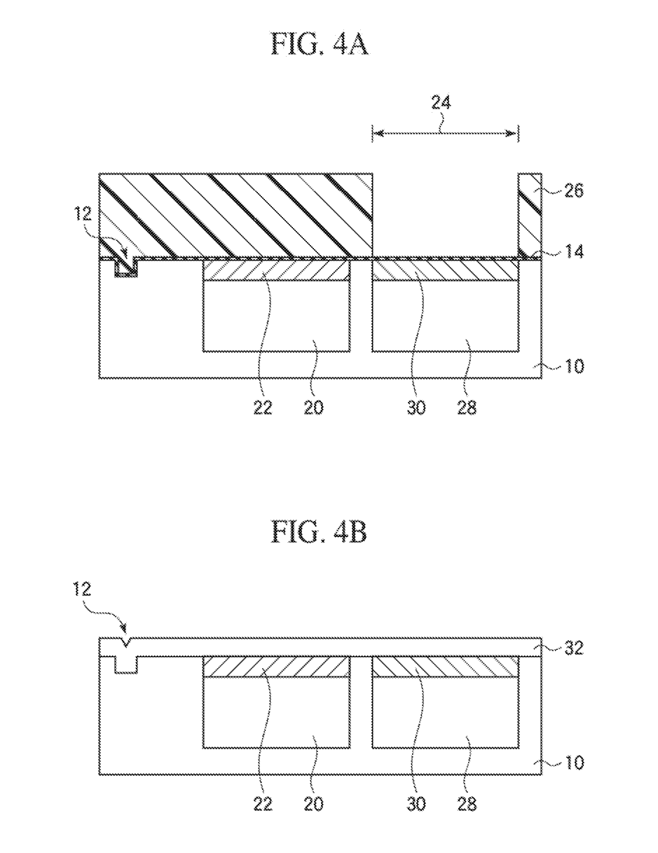

Next, ion implantation is made with the photoresist film 26 as the mask to form an n-well 28 and an n-type highly doped impurity layer 30 in the PMOS transistor forming region 24 of the silicon substrate 10 (FIG. 4A).

The n-well 28 is formed, e.g., by implanting respectively in 4 directions tilted to the normal direction of the substrate phosphorus ions (P⁺) under the conditions of 360 keV acceleration energy and 7.5×10¹² cm⁻² dose and arsenic ions (As⁺) under the conditions of 80 keV acceleration energy and 8×10¹² cm⁻² dose. The n-type highly doped impurity layer 30 is formed, e.g., by implanting arsenic ions under the conditions of 6 keV acceleration energy and 2×10¹³ cm² dose, or antimony ions (Sb⁺) under the conditions of 20 keV-50 keV acceleration energy (e.g., 20 keV) and 0.5×10¹³ cm⁻²-2.0×10¹³ cm² dose (e.g., 1.5×10¹³ cm²). It is preferable that the n-well 28 is formed before the n-type highly doped impurity layer 30.

Next, the photoresist film 26 is removed by, e.g., asking method.

Either of the p-well 20 and the p-type highly doped impurity layer 22, and the n-well 28 and the n-type highly doped impurity layer 22 may be formed first.

Next, thermal processing is made in an inert ambient atmosphere to recover ion implantation damages introduced in the silicon substrate 10 while activating the implanted impurities. For example, the thermal processing of 600° C. and 150 seconds is made in nitrogen ambient atmosphere.

At this time, the p-type highly doped impurity layer 22, in which germanium and carbon are implanted together with boron, can suppress the diffusion of boron, as described above. Thus, the steep distribution of the p-type highly doped impurity layer 22 can be retained. The n-type highly doped impurity layer 30, which includes arsenic or antimony, whose diffusion constant is small, can retain the steep distribution.

Then, the silicon oxide film 14 is removed by wet etching with, e.g., hydrofluoric acid aqueous solution.

Then, the surface of the silicon substrate 10 is etched by about 3 nm by wet etching with, e.g., TMAH (Tetra-Methyl Ammonium Hydroxide). Specifically, the processing of 40° C. and 10 seconds is made with TMAH (10% in water), and then by again making wet etching with hydrofluoric acid aqueous solution, native oxide film formed after the TMAH processing is removed.

Next, a non-doped silicon layer 48 of, e.g., a 30 nm-thickness is grown on the surface of the silicon substrate 10 by, e.g., CVD method (FIG. 4B).

As will be described later in a reference example, much oxygen is present in the surface of the silicon substrate 10 where the silicon layer 32 is grown. By the examination of the inventors of the present application, the much oxygen has been found to be the knock-on oxygen pushed in toward the silicon substrate 10 from the silicon oxide film 14 upon the ion implantations. Because of the large atomic masses of the germanium ions implanted in the NMOS transistor forming region 16 and the arsenic ions or the antimony ions implanted in the PMOS transistor forming region 24, the knock-on will be very influential.

The step of etching the surface of the silicon substrate 10 is for removing the oxygen in the surface of the silicon substrate 10 pushed in upon the ion implantations. The knock-on oxygen in the surface of the silicon substrate 10 is removed in advance, whereby the silicon layer 32 of high crystallinity can be grown.

Increasing the etching amount of the silicon substrate makes more perfect the removal of the knock-on oxygen, but disadvantageously, the implanted impurities are partially removed. The inventors of the present application have found the disadvantage that as the etching amount of the silicon substrate is increased, the surface roughness of the surface of an epitaxial layer to be formed later increases. As shown in FIG. 10, the inventors of the present application have found that to prevent the increase of the surface roughness of the epitaxial layer surface, preferably, the silicon etching amount is not more than about 5 nm.

Next, the surface of the silicon layer 32 is wet oxidized by, e.g., ISSG (In-Situ Steam Generation) method under a reduced pressure to form a silicon oxide film 34 of, e.g., a 3 nm-thickness. As the processing conditions, for example, the temperature is set at 810° C., and the processing period of time is set at 20 seconds.

Then, a silicon nitride film 36 of, e.g., a 90 nm-thickness is deposited above the silicon oxide film 34 by, e.g., LPCVD method. As the processing conditions, for example, the temperature is set at 700° C., and the processing period of time is set at 150 minutes.

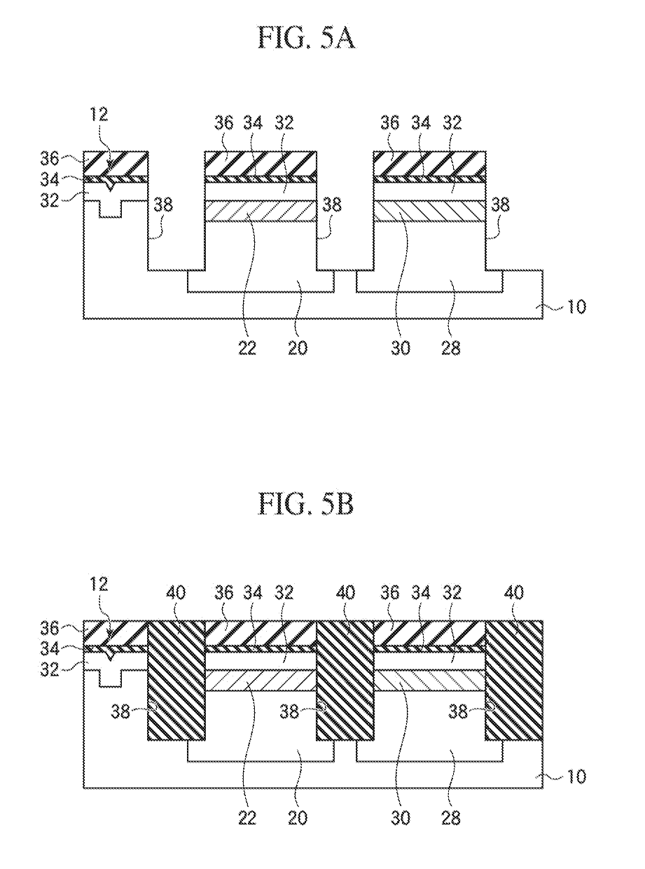

Next, the silicon nitride film 36, the silicon oxide film 34, the silicon layer 32 and the silicon substrate 10 are anisotropically etched by photolithography and dry etching to form a device isolation trench 38 in the device isolation region containing the regions between the respective transistor forming regions (FIG. 5A). The trench 12 is used as the alignment mark for the alignment for the photolithography.

Next, the surface of the silicon layer 32 and the silicon substrate 10 are wet oxidized by, e.g., ISSG method under a decreased pressure to form a silicon oxide film of, e.g., a 2 nm-thickness as the liner film on the inside walls of the device isolation trench 56. As the processing conditions, for example, the temperature is set at 810° C., and the processing period of time is set at 12 seconds.

Next, a silicon oxide film of, e.g., a 500 nm-thickness is deposited by, e.g., high density plasma CVD method to fill the device isolation trench 38 by the silicon oxide film.

Then, the silicon oxide film above the silicon nitride film 36 is removed by, e.g., CMP method. Thus, by the so-called STI (Shallow Trench Isolation) method, the device isolation insulating film 40 of the silicon oxide film buried in the device isolation trench 38 is formed (FIG. 5B).

Next, the device isolation insulating film 40 is etched by, e.g., wet etching with hydrofluoric acid aqueous solution and with the silicon nitride film 36 as the mask by, e.g., about 30 nm. This etching is for adjusting the surface of the silicon layer 32 of the completed transistors and the surface of the device isolation insulating film 40 to be on the substantially the same height.

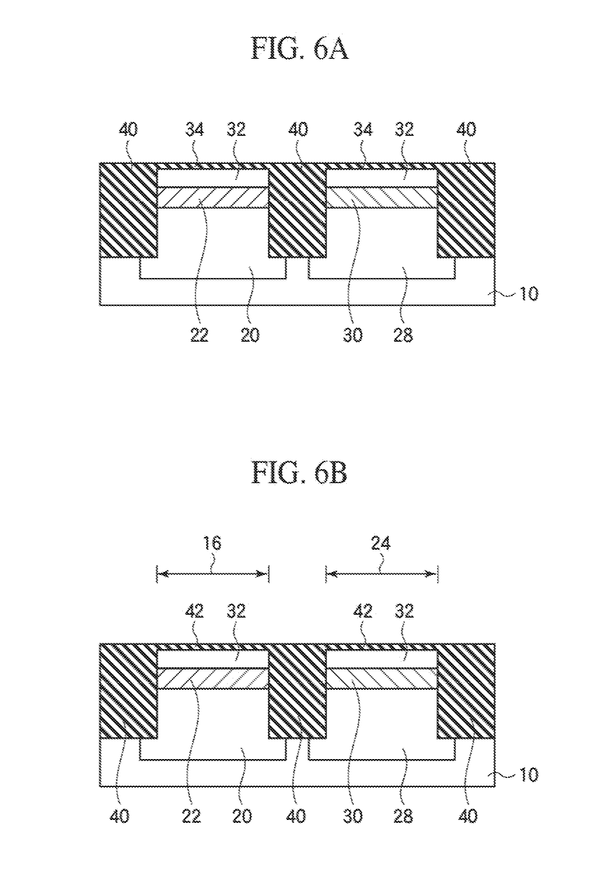

Next, the silicon nitride film 36 is removed by, e.g., wet etching with hot phosphoric acid (FIG. 6A).

Next, the silicon oxide film 34 is removed by, e.g., wet etching with hydrofluoric acid aqueous solution.

Next, a silicon oxide film of, e.g., a 2 nm-thickness is formed by thermal oxidation method. As the processing conditions, for example, the temperature is set at 810° C., and the processing period of time is set at 8 seconds.

Next, thermal processing of, e.g., 870° C. and 13 seconds is made in NO ambient atmosphere to introduce nitrogen into the silicon oxide film.

Thus, the gate insulating films 42 of the silicon oxynitride film are formed in the NMOS transistor forming region 16 and the PMOS transistor forming region 24 (FIG. 6B).

Then, a non-doped polycrystalline silicon film of, e.g., a 100 nm-thickness is deposited above the entire surface by, e.g., LPCVD method. As the processing conditions, for example, the temperature is set at 605° C.

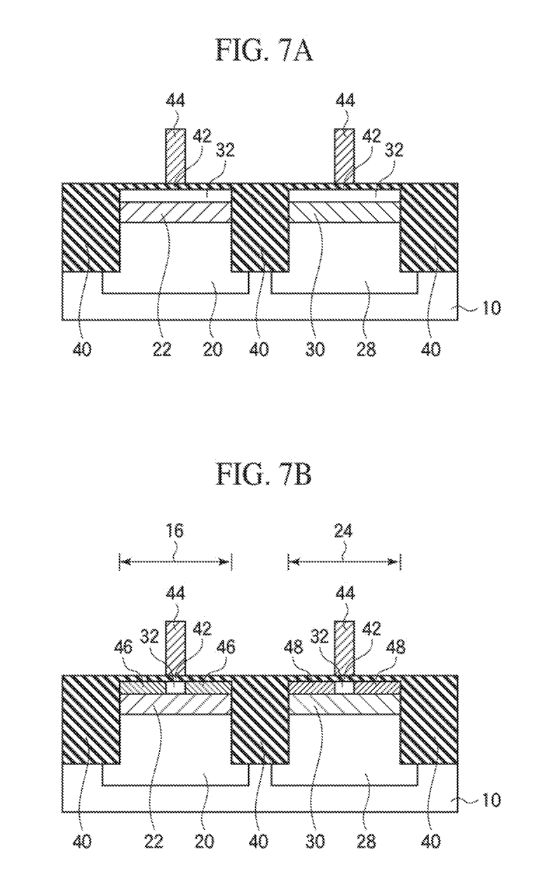

Next, the polycrystalline silicon film is patterned by photolithography and dry etching to form the gate electrodes 44 in the respective transistor forming regions (FIG. 7A).

Next, n-type impurity ions are implanted selectively in the NMOS transistor forming region 16 by photolithography and ion implantation with the gate electrode 44 as the mask to form n-type impurity layers to be the extension regions. The n-type impurity layers 46 are formed by implanting, e.g., arsenic ions under the conditions of 1 keV acceleration energy and 1×10¹⁵ cm⁻² dose.

Next, p-type impurity ions are implanted selectively in the PMOS transistor forming region 24 by photolithography and ion implantation with the gate electrode 44 as the mask to form p-type impurity layers to be the extension regions (FIG. 7B). The p-type impurity layers 48 are formed by implanting, e.g., boron ions under the conditions of 0.3 keV acceleration energy and 3×10¹⁴ cm⁻² dose.

Then, a silicon oxide film of, e.g., an 80 nm-thickness is deposited above the entire surface by, e.g., CVD method. As the processing condition, for example, the temperature is set at 520° C.

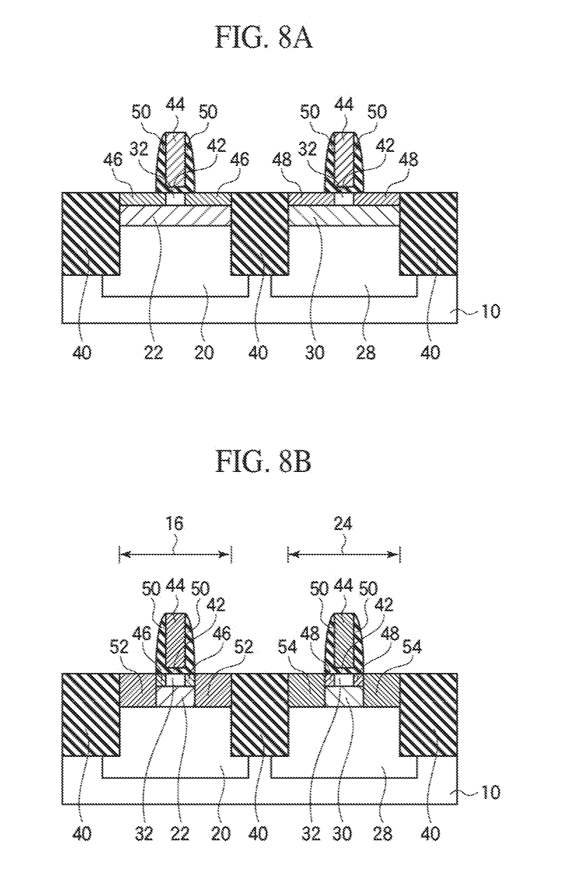

Next, the silicon oxide film deposited above the entire surface is anisotropically etched to be left selectively on the side walls of the gate electrodes 44. Thus, the sidewall spacers 50 of the silicon oxide film are formed (FIG. 8A).

Next, ion implantation is made selectively in the NMOS transistor forming region 16 by photolithography and ion implantation with the gate electrode 44 and the sidewall spacer 50 as the mask. Thus, the n-type impurity layers 52 to be the source/drain regions are formed, and n-type impurities are doped to the gate electrode 44 of the NMOS transistor. As the conditions for the ion implantation, for example, phosphorus ions are ion implanted at 8 keV acceleration energy and at 1.2×10¹⁶ cm⁻² dose.

Next, ion implantation is made selectively in the PMOS transistor forming region 24 by photolithography and ion implantation with the gate electrode 44 and the sidewall spacer 50 as the mask. Thus, the p-type impurity layers 54 to be the source/drain regions are formed, and p-type impurities are doped to the gate electrode 44 of the PMOS transistor. As the conditions for the ion implantation, for example, boron ions are ion implanted at 4 keV acceleration energy and 6×10¹⁵ cm⁻² dose.

Then, rapid thermal processing of, e.g., 1025° C. and 0 second is made in an inert gas ambient atmosphere to activate the implanted impurities and diffuse the impurities in the gate electrodes 44. The thermal processing of 1025° C. and 0 second is sufficient to diffuse the impurities to the interfaces between the gate electrodes 44 and the gate insulating films 42. The channel portion of the NMOS transistor can retain steep impurity distribution by carbon suppressing the diffusion of boron, and the channel portion of the PMOS transistor can retain steep impurity distributions by the slow diffusion of arsenic or antimony.

Thus, the NMOS transistor and the PMOS transistor are respectively formed in the NMOS transistor forming region 16 and the PMOS transistor forming (FIG. 8B).

Then, a metal silicide film 56 of, e.g., a cobalt silicide film is formed on the gate electrodes 44, the n-type impurity layers 52 and the p-type impurity layers 54 by salicide (self-aligned silicide) process.

Next, a silicon nitride film of, e.g., a 50 nm-thickness is deposited above the entire surface by, e.g., CVD method to form the silicon nitride film as the etching stopper film.

Next, a silicon oxide film of, e.g., a 500 nm-thickness is deposited above the silicon nitride film by, e.g., high density plasma CVD method.

Thus, the inter-layer insulating film 58 of the layer film of the silicon nitride film and the silicon oxide film is formed.

Next, the surface of the inter-layer insulating film 58 is polished by, e.g., CMP method to planarize.

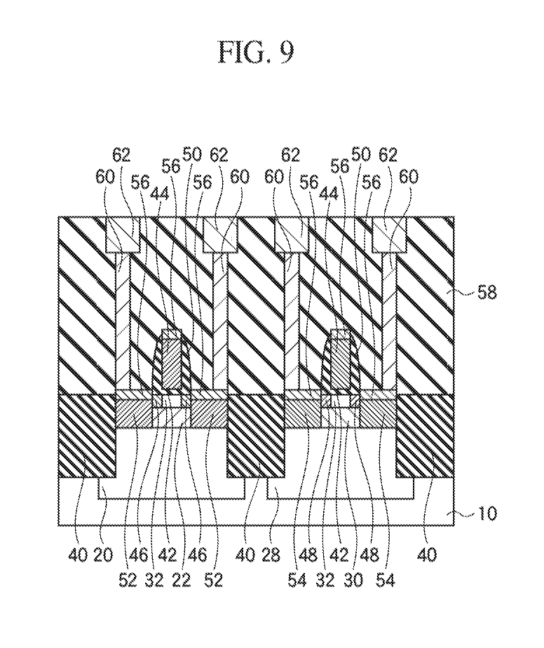

Then, the contact plugs 60 buried in the inter-layer insulating film 58, interconnections 62 connected to the contact plugs 60, and others are formed, and the semiconductor device is completed (FIG. 9).

The result of the examination of the oxygen present in the interface between the silicon layer 32 and the silicon substrate 10 made by the inventors of the present application will be described with reference to FIGS. 11 and 12.

The inventors of the present application had the idea that much oxygen present in the interface between the silicon substrate 10 and the epitaxial silicon layer 32 would be the knock-on oxygen generated upon the ion implantations, and prepared the evaluation samples in the following process flow and examined the oxygen concentrations in the interface.

First, a silicon oxide film was formed on the surface of a silicon substrate. As the silicon oxide film, a 2 nm-thickness silicon oxide film formed by thermal oxidation of 810° C. and 20 seconds or a 0.5 nm-thickness chemical oxide film formed by making sequentially NH₄OH/H₂O₂/H₂O treatment, HF treatment and HCl/H₂O₂/H₂O treatment was used.

Next, germanium ions were implanted in the silicon substrate with the silicon oxide film formed on, assuming the NMOS transistor manufacturing process, or assuming the PMOS transistor manufacturing process, arsenic ions were implanted. The conditions of germanium ion implantation were 60 keV acceleration energy and 5×10¹⁵ cm⁻² dose. The conditions for arsenic ion implantation were 6 keV acceleration energy and 2×10¹³ cm⁻² dose.

Then, thermal processing for recovering the ion implantation damages was made. The thermal processing conditions were 600° C. and 150 minutes.

Next, the silicon oxide film on the silicon substrate surface was removed by wet etching with hydrofluoric acid aqueous solution.

Next, the surface of the silicon substrate was etched by about 3 nm by wet etching with TMAH. For comparison, some samples had the surface of the silicon substrates not etched.

Then, a silicon layer was epitaxially grown on the silicon substrate.

Then, the depth distribution of oxygen atoms of the thus prepared samples were measured by the secondary ion mass spectrometry.

FIGS. 11 and 12 are graphs illustrating the result of the measurement of the oxygen depth distribution in the silicon layer and the silicon substrate by the secondary ion mass spectrometry. FIG. 11 illustrates the result of the measurement of the samples with germanium ion implanted. FIG. 12 illustrates the result of the measurement of the samples with arsenic ion implanted. In each graph, the dotted line indicates the sample in which a 2 nm-thickness silicon oxide film was formed, ion implantation was made, and then the silicon layer was epitaxially grown without etching the surface of the silicon substrate. The one-dot-chain line indicates the sample in which the chemical oxide film was formed, ion implantation was made, and then the silicon layer was epitaxially grown without etching the surface of the silicon substrate. The solid line indicates the sample in which the chemical oxide film was formed, ion implantation was made, and then after the surface of the silicon substrate was etched by 3 nm, the silicon layer was epitaxially grown.

As shown in FIGS. 11 and 12, in the samples having the surface of the silicon substrate not etched before the epitaxial growth (the dotted line and the one-dot-chain line), much oxygen is present in the silicon substrate. On the other hand, the sample having the surface of the silicon substrate etched before the epitaxial growth (the solid line), the oxygen present in the interface between the silicon substrate and the silicon layer is drastically decreased. Based on these results, the oxygen present in the interface between the silicon substrate and the silicon layer has been found the knock-on oxygen pushed in by the ion implantations from the silicon oxide film toward the silicon substrate.

The samples having the surface of the silicon substrate etched before the epitaxial growth could decrease the oxygen concentration to about 1/10 in comparison with the sample having the surface of the silicon substrate not etched before the epitaxial growth.

Based on the above, it has been found that the surface of the silicon substrate is etched before the epitaxial growth, whereby the influence of the knock-on oxygen generated upon the ion implantation is suppressed, and the epitaxial layer of good quality can be formed.

As described above, according to the present embodiment, the surface of the silicon substrate is removed after the highly doped impurity layer has been formed in the channel region and before the epitaxial silicon layer is formed, whereby the oxygen pushed in the silicon substrate by the ion implantation in forming the highly doped impurity layer can be removed. Thus, the epitaxial silicon layer of high crystallinity can be grown. The crystallinity of the epitaxial silicon layer is improved, whereby the characteristics of the transistor and the resultant performance and the reliability of the semiconductor device can be improved.

### A Second Embodiment

A semiconductor device and a method of manufacturing a semiconductor device according to a second embodiment will be described with reference to FIGS. 1 to 20. The same members of the present reference example as those of the semiconductor device and the method of manufacturing the same according to the first embodiment illustrated in FIGS. 1 to 12 are represented by the same reference numbers not to repeat or to simplify the description.

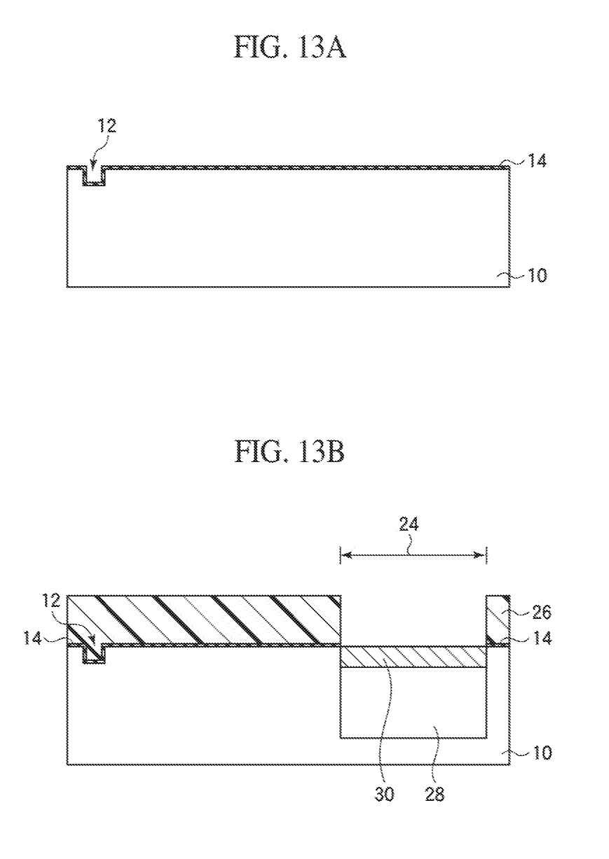

FIGS. 13A-15 are sectional views illustrating the method of manufacturing the semiconductor device according to the present embodiment.

In the present embodiment, another method of manufacturing the semiconductor device according to the first embodiment illustrated in FIG. 1 will be described.

First, a trench 12 to be used as the mark for the mask alignment is formed in a region other than the product to be formed region of the silicon substrate 10 (e.g., a scribe region) by photolithography and etching.

Next, a silicon oxide film 14 as the protection film of the surface of the silicon substrate 10 is formed above the entire surface of the silicon substrate 10 by, e.g., thermal oxidation method (FIG. 13A).

Next, a photoresist film 26 exposing the PMOS transistor forming region 24 and covering the rest region is formed by photolithography. The trench 12 is used as the alignment mark for the alignment for the photolithography.

Next, wet etching with, e.g., hydrofluoric acid aqueous solution is made with the photoresist film 26 as the mask to remove the silicon oxide film 14 in the PMOS transistor forming region 24.

Next, ion implantation is made with the photoresist film 26 as the mask to form an n-well 28 and an n-type highly doped impurity layer 30 are formed in the PMOS transistor forming region 24 of the silicon substrate 10 (FIG. 13B).

The n-well 28 is formed, e.g., by implanting respectively in 4 directions tilted to the normal direction of the substrate phosphorus ions (P⁺) under the conditions of 360 keV acceleration energy and 7.5×10¹² cm⁻² dose and arsenic ions (As⁺) under the conditions of 80 keV acceleration energy and 6×10¹² cm⁻² dose. The n-type highly doped impurity layer 30 is formed, e.g., by implanting arsenic ions under the conditions of 6 keV acceleration energy and 2×10¹³ cm⁻² dose, or antimony ions (Sb⁺) under the conditions of 20 keV-50 keV acceleration energy (e.g., 20 keV) and 0.5×10¹³ cm⁻²-2.0×10¹³ cm² dose (e.g., 1.5×10¹³ cm⁻²).

At this time, the silicon oxide film 14 has not been formed on the surface of the silicon substrate 10 in the PMOS transistor forming region 24. When the wafer is stored in the atmosphere even temporarily, often oxygen is present in the surface of the silicon substrate 10 due to the growth of native oxide film, etc., but the quantity of the oxygen in the surface of the silicon substrate 10 drastically decreases. Thus, the quantity of the oxygen to be pushed into the silicon substrate 10 by the knock-on due to the ion implantation in forming the n-well 28 and the n-type highly doped impurity layer 30.

The photoresist film 26 might be formed directly on the silicon substrate 10 without forming the silicon oxide film 14. However, unpreferably, in this method, the temperature of the silicon substrate 10 and the photoresist film 26 rises in the ion implantation, and mobile ions, etc. in the photoresist film 26 diffuse to contaminate the silicon substrate 10.

Next, the photoresist film 26 is removed by, e.g., asking method.

Next, the silicon oxide film 14 is removed by wet etching with, e.g., hydrofluoric acid aqueous solution.

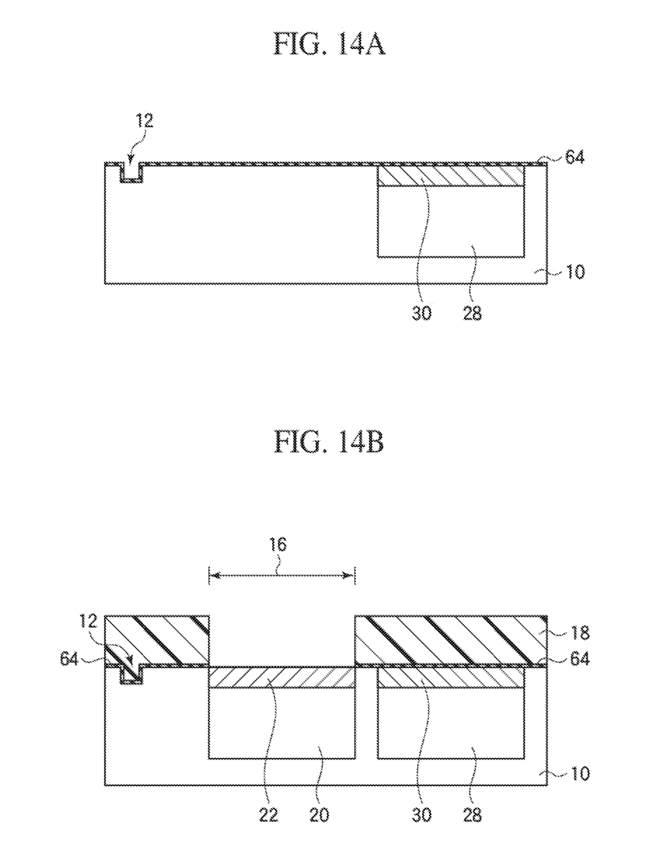

Next, a silicon oxide film 64 as the protection film of the surface of the silicon substrate 10 is formed above the entire surface of the silicon substrate 10 by, e.g., thermal oxidation method (FIG. 14A).

Next, a photoresist film 18 exposing the NMOS transistor forming region 16 and covering the rest region is formed by photolithography. The trench 12 is used as the alignment mark for the alignment for the photolithography.

Next, wet etching with, e.g., hydrofluoric acid aqueous solution is made with the photoresist film 18 as the mask to remove the silicon oxide film 64 in the NMOS transistor forming region 16.

Next, ion implantation is made with the photoresist film 18 as the mask to form a p-well 20 and a p-type highly doped impurity layer 22 in the NMOS transistor forming region 16 (FIG. 14B).

The p-well 20 is formed, e.g., by implanting boron ions (B⁺) respectively in 4 directions tilted to the normal direction of the substrate under the conditions of 150 keV acceleration energy and 7.5×10¹² cm⁻² dose. The p-type highly doped impurity layer 22 is formed, e.g., by respectively implanting germanium ions (Ge⁺) under the conditions of 50 keV acceleration energy and 5×10¹⁴ cm⁻², carbon ions (C⁺) under the conditions of 3 keV acceleration energy and 3×10¹⁴ cm² and boron ions (B⁺) under the conditions of 2 keV acceleration energy and 3×10¹³ cm².

At this time, the silicon oxide film 64 has not been formed on the surface of the silicon substrate 10 in the NMOS transistor forming region 16. When the wafer is stored in the atmosphere even temporarily, often oxygen is present in the surface of the silicon substrate 10 due to the growth of native oxide film, etc., but the quantity of the oxygen in the surface of the silicon substrate 10 drastically decreases. Thus, the quantity of the oxygen to be pushed into the silicon substrate 10 by the knock-on due to the ion implantation in forming the p-well 20 and the p-type highly doped impurity layer 22.

The photoresist film 18 might be formed directly on the silicon substrate 10 without forming the silicon oxide film 64. However, unpreferably, in this method, the temperature of the silicon substrate 10 and the photoresist film 18 rises in the ion implantation, and mobile ions, etc. in the photoresist film 26 diffuse to contaminate the silicon substrate 10.

Next, the photoresist film 18 is removed by, e.g., asking method.

In the method of manufacturing the semiconductor device according to the present embodiment, the n-well 28 and the n-type highly doped impurity layer 30 are formed before the p-well 20 and the p-type highly doped impurity layer 22. This is for suppressing the enhanced diffusion of the impurities due to the oxidation.

The enhanced diffusion of boron and carbon is very large in comparison with arsenic, antimony and phosphorus. When the silicon oxide film to be the protection film for forming the n-well 28 and the n-type highly doped impurity layer 30 is formed by oxidizing the silicon substrate 10 after the formation of the p-well 20 and the p-type highly doped impurity layer, the enhanced diffusion of boron and carbon take places in the process of forming the protection film. When carbon positioned at the lattice points of the silicon substrate surface decreases, the effect of suppressing the boron diffusion is reduced, and the p-type highly doped impurity layer 22 having a steep boron concentration distribution cannot be formed.

By forming the p-well 20 and the p-type highly doped impurity layer 22 after the n-well 28 and the n-type highly doped impurity layer 30, the enhanced diffusion of the boron and the carbon does not take place in forming the silicon oxide film as the protection film. The arsenic, antimony and phosphorus contained in the n-well 28 and the n-type highly doped impurity layer 30 are exposed to the oxidation process, but the enhanced diffusion of them is small in comparison with the boron and the carbon.

Accordingly, the p-well 20 and the p-type highly doped impurity layer 22 are formed after the n-well 28 and the n-type highly doped impurity layer 30, whereby both the n-type highly doped impurity layer 30 and the p-type highly doped impurity layer 22 can have steep impurity concentration distributions.

As described above, in the present embodiment, the n-well 28 and the n-type highly doped impurity layer 30 are formed before the p-well 20 and the p-type highly doped impurity layer 22 so as to prevent the enhanced diffusion of the impurities due to the oxidation. The enhanced diffusion does not take place when a film deposited by CVD method or others is used as the protection film for the ion implantation, and either of the p-well 20 and the p-type highly doped impurity layer 22, and the n-well 28 and the n-type highly doped impurity layer 30 may be formed in advance.

Next, thermal processing is made in an inert ambient atmosphere to recover ion implantation damages introduced in the silicon substrate 10 while activating the implanted impurities. For example, the thermal processing of 600° C. and 150 seconds is made in nitrogen ambient atmosphere.

Then, the silicon oxide film 64 is removed by wet etching with, e.g., hydrofluoric acid aqueous solution.

Then, the surface of the silicon substrate 10 is etched by wet etching with, e.g., TMAH (Tetra-Methyl Ammonium Hydroxide) by about 3 nm. This etching is made for removing the knock-on oxygen pushed in the silicon substrate 10 in forming the p-type highly doped impurity layer 22 and the n-type highly doped impurity layer 30.

In the present embodiment, in which the ion implantation is made without the silicon oxide films 14, 64 to thereby reduce the quantity of the know-on oxygen, it is not essential to etch the silicon substrate 10. However, in consideration of native oxide film formed during the wafer storage, it is preferable that the surface of the silicon substrate 10 is etched in the present embodiment as well.

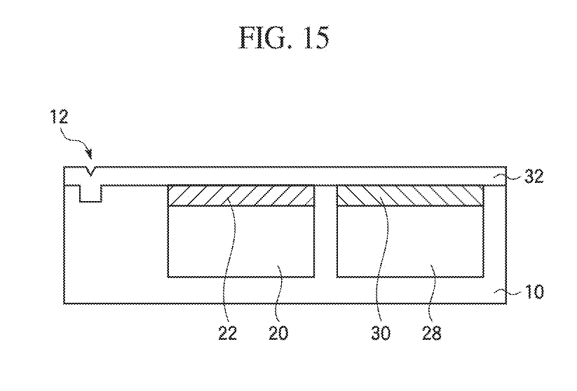

Next, the non-doped silicon layer 32 of, e.g., a 30 nm-thickness is epitaxially grown on the surface of the silicon substrate 10 by, e.g., CVD method (FIG. 15).

Then, in the same way as in the method of manufacturing the semiconductor device according to the first embodiment illustrated in FIG. 5A to FIG. 9, the semiconductor device is completed.

As described above, according to the present embodiment, when the highly doped impurity layer is formed in the channel region, the protection film in the ion implanted region has been removed, whereby the quantity of oxygen to be pushed into the silicon substrate upon the ion implantation in forming the highly doped impurity layer can be drastically decreased. Thus, the epitaxial silicon layer of high crystallinity can be grown. The crystallinity of the epitaxial silicon layer is improved, whereby the characteristics of the transistors can be improved, and resultantly, the performance and reliability of the semiconductor device can be improved.

### A Reference Example

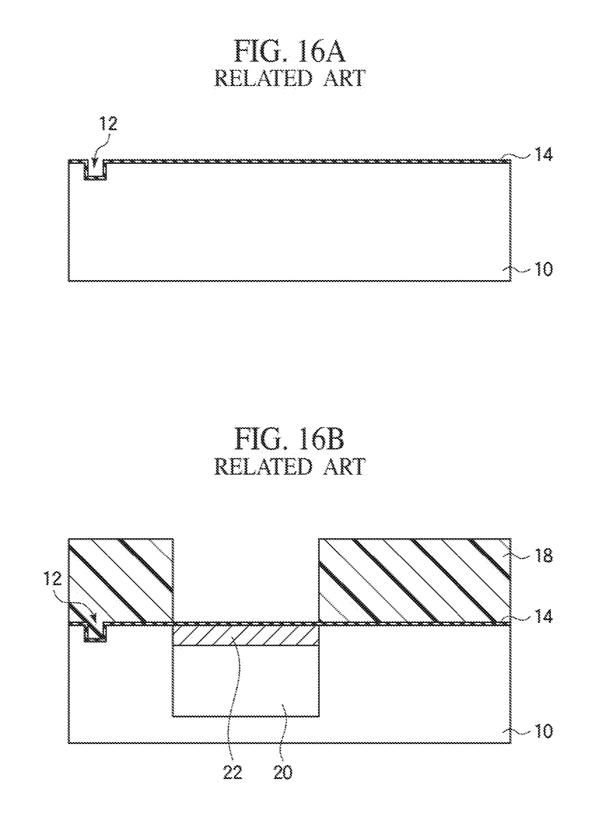

A method of manufacturing a semiconductor device according to a reference example will be described with reference to FIGS. 16A-19. The same members of the present reference example as those of the semiconductor device and the method of manufacturing the same according to the first and the second embodiments illustrated in FIGS. 1 to 15 are represented by the same reference numbers not to repeat or to simplify the description.

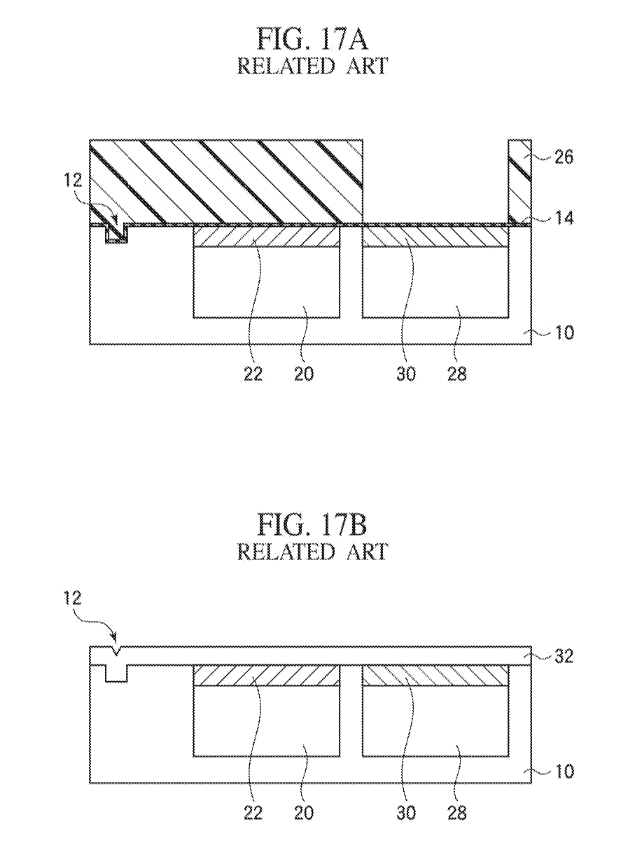

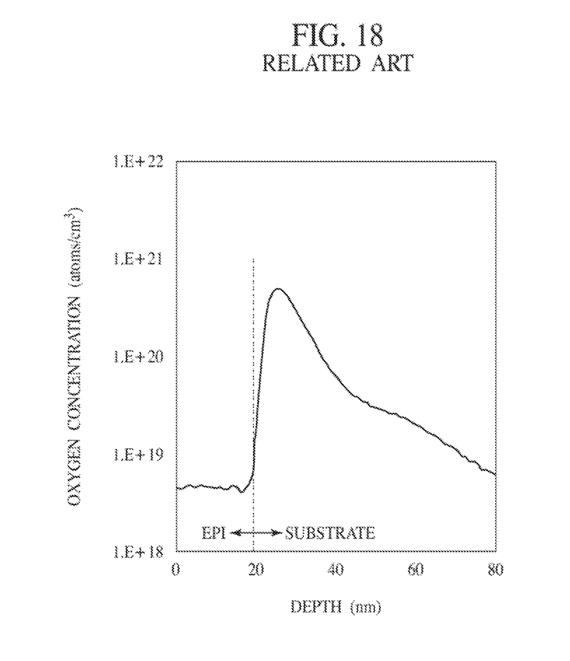

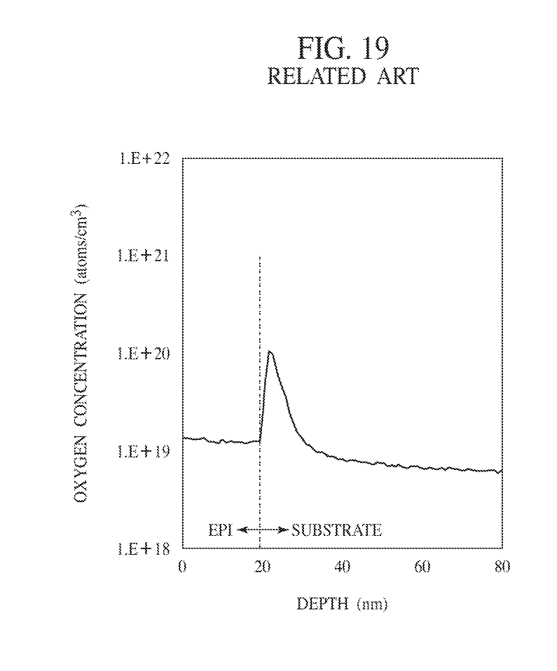

FIGS. 16A-17B are sectional views illustrating the method of manufacturing the semiconductor device according to the present reference example. FIGS. 18 and 19 are graphs illustrating the depth distributions of oxygen in the silicon substrate.

First, a trench 12 to be used as the mark for the mask alignment is formed in a region other than the product to be formed region of the silicon substrate 10 by photolithography and etching.

Next, a silicon oxide film 14 as the protection film of the surface of the silicon substrate 10 is formed above the entire surface of the silicon substrate 10 (FIG. 16A).

Next, a photoresist film 18 exposing the NMOS transistor forming region 16 and covering the rest region is formed by photolithography.

Next, ion implantation is made with the photoresist film 18 as the mask to form a p-well 20 and a p-type highly doped impurity layer 22 in the NMOS transistor forming region 16 (FIG. 16B).

Next, the photoresist film 18 is removed by, e.g., ashing method.

Next, a photoresist film 26 exposing the PMOS transistor forming region 24 and covering the rest region is formed by photolithography.

Next, ion implantation is made with the photoresist film 26 as the mask to form an n-well 28 and an n-type highly doped impurity layer 30 are formed in the PMOS transistor forming region 24 of the silicon substrate 10 (FIG. 17A).

Next, the photoresist film 26 is removed by, e.g., ashing method.

Next, thermal processing is made in an inert ambient atmosphere to recover ion implantation damages introduced in the silicon substrate 10 while activating the implanted impurities.

Then, the silicon oxide film 14 is removed by wet etching with hydrofluoric acid aqueous solution.

Next, the non-doped silicon layer 32 is epitaxially grown on the surface of the silicon substrate 10 (FIG. 17B).

Then, in the same way as in the method of manufacturing the semiconductor device according to the first embodiment illustrated in FIG. 5A to FIG. 9, the semiconductor device is completed.

The inventors of the present application examined the semiconductor device prepared by the manufacturing method described above and have found that the silicon layer 32 of the epitaxially grown on the silicon substrate 10 had poor crystallinity. The inventors of the present application examined this and have found that a large quantity of oxygen present in the surface of the silicon substrate 10 on which the silicon layer 32 is epitaxially grown was a cause. With oxygen present in the surface of the silicon substrate 10 on which the silicon layer 32 is epitaxially grown, the crystallinity of the grown silicon layer 32 is degraded, which resultantly causes the degradation of the transistor characteristics.

FIGS. 18 and 19 are graphs illustrating the depth distributions of oxygen in the silicon layer and the silicon substrate measured by the second ion mass spectrometry. FIG. 18 is the measurement result of the NMOS transistor forming region 16, and FIG. 19 is the measurement result of the PMOS transistor forming region 24.

As shown in FIGS. 18 and 19, in both of the NMOS transistor forming region 16 and the PMOS transistor forming region 24, a high concentration of oxygen is present near the interface between the silicon layer 32 and the silicon substrate 10.

### Modified Embodiments

The above-described embodiment can cover other various modifications.

For example, in the above-described embodiments, the method of manufacturing the transistor including the epitaxial layer on the channel impurity layer is exemplified. However, the embodiments can be applicable to various method of manufacturing the semiconductor device including the step of growing an epitaxial layer on a semiconductor substrate after an impurity layer has been formed. Especially, in the method of manufacturing the semiconductor device including the step of making ion implantation with a surface layer containing oxygen, such as oxide film or adsorbed oxygen, etc., formed on the surface of a semiconductor substrate, the effects as in the above-described embodiments can be expected.

In the above-described embodiments, the phenomenon that the oxygen in the silicon oxide film is pushed into the silicon substrate by the ion implantation is described. However, the knock-on due to the ion implantation is not limited to oxygen. For example, when ion implantation is made with silicon nitride film formed on a silicon substrate, the nitrogen in the silicon nitride film is pushed into the silicon substrate by the know-on. The knocked-on atoms other than silicon pushed into the silicon substrate will affect the growth of the epitaxial layer. The step of removing the surface of the silicon substrate before the growth of the epitaxial layer is effective even when any film is used as the protection film for the ion implantation.

In the above-described embodiment, as the base semiconductor substrate, a silicon substrate is used, but the base semiconductor substrate may not be essentially a bulk silicon substrate. Other semiconductor substrates, such as SOI substrate, etc., may be used.

In the above-described embodiment, as the epitaxially semiconductor layer, a silicon layer is used, but the silicon layer is not essential. In place of the silicon layer, other semiconductor layers, such as SiGe layer, SiC layer, etc., may be used.

The structure, the constituent material, the manufacturing conditions, etc. of the semiconductor device described in the embodiment described above are one example and can be changed or modified suitably in accordance with the technical common sense, etc. of those skilled in the art.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present inventions have been described in detail, it should be understood that the various changes, substitutions, and alterations could be made hereto without departing from the spirit and scope of the invention.

What is claimed is:

1. A method of manufacturing a semiconductor device comprising:
forming a protection film above a semiconductor substrate;
forming an impurity layer in the semiconductor substrate by ion implanting an impurity in the semiconductor substrate through the protection film;
removing the protection film after forming the impurity layer;
removing at least silicon that is component of a surface portion, that includes the impurity layer, of the semiconductor substrate after removing the protection film;
epitaxially growing a semiconductor layer above the semiconductor substrate after removing at least silicon;
forming a gate insulating film above the semiconductor layer;
forming a gate electrode above the gate insulating film; and
after forming the gate electrode, forming a source/drain region in the semiconductor layer,
wherein the semiconductor device includes a transistor having a first region in the semiconductor layer below the gate insulating film with a first impurity concentration, and a second region in the semiconductor layer below the first region with a second impurity concentration which is higher than the first impurity concentration,
wherein constituent atoms of the protection film pushed into the semiconductor substrate upon ion implanting the impurity is removed in removing at least silicon.

2. The method of manufacturing a semiconductor device according to claim 1, wherein removing the protection film includes wet etching with a first solution, and removing at least silicon that is component of the surface portion includes wet etching with a second solution is different from the first solution.

3. The method of manufacturing a semiconductor device according to claim 2, wherein the first solution is a hydrofluoric acid aqueous solution, and the second solution is a solution of tetra-methyl ammonium hydroxide.

4. The method of manufacturing a semiconductor device according to claim 1, wherein an etching thickness of the semiconductor substrate is from 3 nm to 5 nm in removing at least silicon.

5. The method of manufacturing a semiconductor device according to claim 1, wherein a concentration of the constituent atoms removed in the removing at least silicon is about 9/10 of a concentration of the constituent atoms pushed into the semiconductor substrate by the ion implanting.

6. A method of manufacturing a semiconductor device comprising:
forming a protection film above a semiconductor substrate;
forming an impurity layer in the semiconductor substrate by ion implanting an impurity in the semiconductor substrate through the protection film;
removing the protection film after forming the impurity layer;
removing at least silicon that is component of a surface portion, that includes the impurity layer, of the semiconductor substrate after removing the protection film;
epitaxially growing a semiconductor layer above the semiconductor substrate after removing at least silicon;
forming a gate insulating film above the semiconductor layer;
forming a gate electrode above the gate insulating film; and
after forming the gate electrode, forming a source/drain region in the semiconductor layer,
wherein the semiconductor device includes a transistor having a first region in the semiconductor layer below the gate insulating film with a first impurity concentration, and a second region in the semiconductor layer below the first region with a second impurity concentration which is higher than the first impurity concentration,
wherein, oxygen is pushed into the semiconductor substrate by the ion implanting in the forming the impurity layer, and the oxygen, that is pushed into the semiconductor substrate, is removed in the removing at least silicon.

7. The method of manufacturing a semiconductor device according to claim 6, wherein removing the protection film includes wet etching with a first solution, and removing at least silicon that is component of the surface portion includes wet etching with a second solution that is different from the first solution.

8. The method of manufacturing a semiconductor device according to claim 7, wherein the first solution is a hydrofluoric acid aqueous solution, and the second solution is a solution of tetra-methyl ammonium hydroxide.

9. The method of manufacturing a semiconductor device according to claim 6, wherein an etching thickness of the semiconductor substrate is from 3 nm to 5 nm in removing at least silicon.

10. The method of manufacturing a semiconductor device according to claim 6, wherein a concentration of the oxygen removed in the removing at least silicon is about 9/10 of a concentration of the oxygen pushed into the semiconductor substrate by the ion implanting.
